(19) United States
(12) Patent Application Publication
(10) Pub. No.: US 2004/0175948 A1
(43) Pub. Date: Sep. 9, 2004

(54) Metal chelation in carbon dioxide

(75) Inventors: Joseph M. DeSimone, Chapel Hill, NC (US); Pamela M. Visintin, Carrboro, NC (US); Ginger M. Denison, Durham, NC (US); Carol A. Bessel, Norristown, PA (US); Cynthia K. Schauer, Carrboro, NC (US); Stephen Gross, Chapel Hill, NC (US)

Correspondence Address: MYERS BIGEL SIBLEY & SAJOVEC, PO BOX 37428, RALEIGH, NC, 27627, US

(73) Assignee: The University of North Carolina at Chapel Hill

(21) Appl. No.: 10/683,049

(22) Filed: Oct. 10, 2003

Related U.S. Application Data
(60) Provisional application No. 60/417,707, filed on Oct. 10, 2002.

(51) Int. Cl. H01L 21/302; H01L 21/461

(52) U.S. Cl. 438/690

(57) ABSTRACT

Chemical mechanical polishing compositions including a carbon dioxide-based solvent, an oxidizing agent, and a chelating agent are formed and used with CMP processes and systems. Methods for determining the endpoint of a CMP process are also provided.

### CROSS REFERENCE TO RELATED APPLICATIONS

This application claims the benefit of, and incorporates herein by reference in its entirety, the following United States Provisional Application: U.S. Provisional Application No. 60/417,707, filed Oct. 10, 2002.

### FIELD OF THE INVENTION

The present invention relates to carbon dioxide chelating compositions, methods of using such compositions, and apparatus employing such compositions.

### BACKGROUND OF THE INVENTION

The microelectronics industry is currently researching and developing new metallic interconnect materials and structures which can be used within integrated circuits (ICs). A promising metallic material that may be used for integrated circuit interconnects is copper (Cu). Copper is a promising metallic material because it has improved electromigration resistance over aluminum, and other metallic materials that are currently being used in the integrated circuit industry. In addition, copper has a lower resistivity than other commonly used metallic materials such as tungsten. Copper interconnects may also allow an integrated circuit to use higher critical current. Thus, it is believed that the performance of integrated circuit devices can be greatly improved through the use of copper interconnects.

While the foregoing physical characteristics make copper a promising material, difficulties have been encountered when attempting to adequately form functional copper interconnects over the surface of an integrated circuit. There is a lack of technology which can effectively plasma etch or wet etch copper materials so that functional copper interconnects are formed. In order to overcome this limitation, the use of aqueous slurries for copper chemical mechanical polishing or planarization (CMP) has been investigated.

For example, U.S. Pat. No. 6,001,730 to Farkas et al. propose a two-step chemical mechanical polishing (CMP) process for forming a copper interconnect on an integrated circuit wherein the copper interconnect uses a tantalum-based barrier layer. The patent proposes an aqueous and/or alcohol based slurry that includes a hydrogen peroxide oxidizing agent, a carboxylate salt such as a citrate salt, an abrasive agent, and an optional triazole or triazole derivative.

U.S. Pat. No. 6,169,034 to Avanzino et al. proposes an aqueous CMP slurry containing a particulate material, such as a mineral, having a hardness no greater than about Mohs 6.

U.S. Pat. No. 6,362,104 to Wang et al. proposes an aqueous chemical mechanical polishing composition that includes at least one oxidizing agent and at least one solid catalyst. The patent further proposes an aqueous chemical mechanical polishing slurry that includes from about 0.5 to about 0.7 weight percent of an abrasive selected from silica, alumina, and mixtures thereof, at least one photoactivated solid catalyst, and an oxidizing agent selected from the group including monopersulfate, di-persulfate, peracetic acid, urea hydrogen peroxide, hydrogen peroxide, acids thereof, salts thereof, adducts thereof, or mixtures thereof.

U.S. Pat. No. 6,364,744 to Merchant et al. proposes a CMP slurry that includes an aqueous phase which is preferably an aqueous acidic phase. The slurry includes abrasive particles comprised of metal oxides such as silica, alumina, titanium oxide, and cerium oxide. The slurry further includes at least one mixed metal oxide such as SrTiO₃, CeTiO₃, BaTiO₃, or (SrₓBa₁₋ₓ)TiO₃.

U.S. Pat. No. 6,435,944 to Wang et al. proposes an aqueous CMP slurry that includes an oxidizing moiety and a complexing moiety, where the reduced form of the oxidizing moiety comprises a complexing agent for the metal, such as peroxy acids including peroxybenzoic acid, chloroperoxybenzoic acid, peroxyacetic acid, and peroxyformic acid.

U.S. Pat. No. 6,458,289 to Merchant et al. proposes a CMP slurry that includes a first emulsion having a continuous aqueous phase that includes abrasive particles and a second emulsion having an organic phase and a dispersed aqueous phase for capturing metal particles polished from a semiconductor wafer.

Such aqueous-based slurries may be incompatible with new low κ dielectric materials (ILD), especially when such materials are porous. Additionally, aqueous-based slurries may limit the lower temperature at which CMP may be performed, thus limiting the ability to dissipate heat during the CMP process. Moreover, aqueous-based slurries may exhibit less than ideal wetting properties. Water has a high surface tension, which limits or prevents access to high aspect ratio features such as trenches. Furthermore, ultrapure water, which is quite expensive, is required for CMP processes in order to reduce or eliminate particulates, acids, metals, ions, and/or bases that may deposit on the wafer surface. The volume of water per wafer needed to perform CMP processes may also result in the production of an excessive amount of environmental waste.

U.S. Pat. No. 6,623,355 to McClain et al. proposes the use of carbon dioxide as an alternative to aqueous solvents in CMP processes.

Published U.S. Patent Application No. 20030051741 AI to DeSimone et al. proposes the use of carbon dioxide for cleaning microelectronic devices.

Published U.S. Patent Application No. 20020112740 Al to DeYoung et al. proposes the use of carbon dioxide drying compositions for cleaning and removing water and entrained solutes from microelectronic devices.

Supercritical fluids have been proposed for use in various non-CMP microelectronic processes such as post-CMP cleaning processes, contamination removal processes, and etching processes.

For example, U.S. Pat. No. 6,277,753 to Mullee et al. proposes a method for removing the residue that remains on a semiconductor substrate after the completion of a CMP process. The proposed method includes placing a semiconductor substrate having CMP residue thereon in a pressure chamber, pressurizing the chamber, introducing supercritical carbon dioxide and a solvent into the pressure chamber, and maintaining the supercritical carbon dioxide and the solvent in contact with the semiconductor substrate until the CMP residue is removed from the semiconductor substrate.

U.S. Pat. No. 5,868,856 to Douglas et al. proposes a method of removing inorganic contamination from the surface of a semiconductor substrate that includes reacting the inorganic contaminant with at least one conversion agent that is an acid (preferably KCN, HF, HCl, or KI), a base (preferably NH₄OH, KOH, or NF₃), or a chelating and/or ligand agent (preferably beta-diketone) thereby converting the inorganic contamination, and removing the converted inorganic contamination by subjecting it to at least one solvent agent in a supercritical fluid, preferably supercritical CO₂. The converted inorganic contamination is more highly soluble in the solvent agent than in the inorganic contamination.

U.S. Pat. No. 5,868,862 to Douglas et al. also proposes a method of removing inorganic contamination from the surface of a semiconductor substrate. The method includes removing a native oxide in which overlies the inorganic contamination (and/or that is situated between the inorganic contamination and the substrate and/or that surrounds the inorganic contamination) thereby exposing the inorganic contamination, chemically altering the inorganic contamination such that it is soluble in a conventional solvent, exposing the chemically-altered inorganic contaminant to a conventional solvent that is included in a supercritical fluid, and removing the conventionally-solvated, chemically-altered inorganic contaminant in a supercritical fluid.

U.S. Pat. No. 6,149,828 to Vaartstra proposes supercritical etching compositions useful for etching an inorganic material of a semiconductor substrate. The supercritical etching compositions include a supercritical component such as ammonia, amines, alcohols, water, carbon dioxide, nitrous oxide, inert gases, hydrogen halides, hydrochloric acid, hydrobromic acid, boron trichloride, chlorine, fluorine, hydrocarbons, methane, ethane, propane, fluorocarbons, hexafluoroacetylacetone, and similar compounds, or combinations thereof. The patent states that the supercritical etching compositions may also include additional components, namely oxidizers (e.g., hydrogen peroxide, nitrogen trifluoride, ozone, oxygen, halogens, sulfur dioxide, and sulfur trioxide), buffering agents (e.g., ammonium fluoride or tetramethylammonium fluoride), surfactants, selectivity enhancers (e.g., tetramethyl ammonium hydroxide, tetramethyl nitrogen fluoride, and ammonium fluoride), or ligands (e.g., beta-diketones, fluorinated-diketones, or organic acids), but provides no guidance as to the amount in which such additional components should be employed. Furthermore, the patent appears to provide no guidance as to whether mixtures of such additional components can be utilized, and, if such mixtures were utilized, in what relative amounts the additional components should be employed.

In addition to the ability to effectively remove the desired metallic material by use of the chemical mechanical polishing process, an important consideration when performing chemical mechanical polishing of a substrate is the determination of the endpoint of the CMP process. Semiconductor manufacturers often monitor wafers before, during and after the formation of semiconductor devices. Manufacturers may monitor the wafers to ensure, for example, that the removal rate from a CMP process is within process specifications. Off-line measurements may tend to dominate the current mode of measurement. Such off-line measurements may cause semiconductor manufacturers to lose up to several hours per shift measuring the wafers off-line. This loss of production time effectively reduces the CMP equipment capacity. Various approaches have been tried to provide in-line (immediately after processing) or in-situ (during processing) measurements.

For example, U.S. Pat. No. 6,179,691 to Lee et al. proposes the addition of a copper isotope to the layer of copper that is deposited to form the metal interface. While the copper layer is etched, the radioactivity emitted by the copper layer will decrease as the volume of the copper layer decreases. Endpoint of the copper CMP is reached at the time when the copper radioactivity starts to rapidly decrease.

U.S. Pat. No. 6,287,171 to Meloni proposes in-situ endpoint detection in CMP by immersing a surface plasmon resonance sensor having a conducting layer in a slurry near the wafer, introducing a light source into the surface plasmon resonance sensor, and measuring the surface plasmon resonance signal produced thereby to determine a reduction of metal to metal oxide or metal hydroxide to determine the amount of free metal in the slurry.

Such endpoint detection methods are less than ideal because, for example, they utilize radioactive materials, with all of the attendant personnel and environmental concerns, or utilize fairly complex sensors that have to be placed near the surface of the wafer.

Accordingly, a need exists in the industry for an improved CMP slurry which may be more compatible with new low κ dielectric materials than aqueous-based slurries, may have better wetting properties than aqueous-based slurries, and/or may provide the ability to perform CMP at lower temperatures than those allowed with aqueous-based slurries while allowing for the use of homogeneous CMP compositions and/or CMP compositions that use a lower oxidation state of the metal, which may allow for the use of lower amounts of oxidants and/or chelants or are more specific for the desired metal. It may also be beneficial if such slurries provided a simpler, more environmentally-friendly way of determining CMP endpoint, either in-line or in-situ.

### SUMMARY OF THE INVENTION

Embodiments of the present invention provide carbon dioxide-based CMP compositions, methods, and systems that combine the benefits of carbon dioxide-based CMP, such as better wetting properties, ability to perform CMP at a lower temperature, and better integration with other aspects of semiconductor processing, with the benefits of using a homogeneous CMP solution, which may provide more uniform polishing and better reaction rates, for example. Embodiments of the present invention also allow carbon dioxide-based CMP to be performed such that a metal, M[0], is oxidized to M[I], instead of M[II]. Embodiments of the present invention may allow for the use of lower amounts of oxidants and/or chelating agents than conventional processes.

According to embodiments of the present invention, a chemical mechanical polishing composition includes a carbon dioxide-based solvent, an oxidizing agent capable of oxidizing a metal, M[0], to provide an oxidized metal, M[II], and a fluorinated beta-diketone chelating agent. In some embodiments, the metal is Cu[0] and the oxidized metal is Cu[II]. In some embodiments, the oxidizing agent is soluble in the carbon dioxide-based solvent, the fluorinated beta-diketonate chelating agent is soluble in the carbon dioxide-based solvent, and the composition is a homogeneous composition.

According to other embodiments of the present invention, a chemical mechanical polishing composition includes a carbon dioxide-based solvent, an oxidizing agent, and a fluorinated beta-diketonate chelating agent. In some embodiments, the oxidizing agent is soluble in the carbon dioxide-based solvent, the fluorinated beta-diketonate chelating agent is soluble in the carbon dioxide-based solvent, and the composition is a homogeneous composition.

According to still other embodiments of the present invention, a chemical mechanical polishing composition includes a carbon dioxide-based solvent, an oxidizing agent capable of oxidizing a metal, M[0], to provide an oxidized metal, M[I], and a chelating agent capable of chelating the oxidized metal, M[I]. In some embodiments, the oxidizing agent is soluble in the carbon dioxide-based solvent, the chelating agent is soluble in the carbon dioxide-based solvent, and the composition is a homogeneous composition.

According to yet other embodiments of the present invention, a homogeneous composition includes a carbon dioxide-based solvent, molecular iodine, and a phosphine that is soluble in the carbon dioxide-based solvent.

According to other embodiments of the present invention, a chemical mechanical composition for polishing a substrate including at least one metal layer includes a carbon dioxide-based solvent, and an oxidizing and chelating agent capable of oxidizing a metal in the at least one metal layer and chelating the oxidized metal.

According to still other embodiments of the present invention, a method for polishing a substrate including at least one metal layer includes contacting the substrate with a chemical polishing composition that comprises a carbon dioxide-based solvent, an oxidizing agent capable of oxidizing a metal, M[0], to provide an oxidized metal, M[II], and a fluorinated beta-diketone chelating agent to remove at least a portion of the at least one metal layer from the substrate thereby polishing the substrate.

According to yet other embodiments of the present invention, a method for polishing a substrate including at least one metal layer includes contacting the substrate with a chemical polishing composition that comprises a carbon dioxide-based solvent, an oxidizing agent capable of oxidizing a metal, M[0], to provide an oxidized metal, M[I], and a chelating agent capable of chelating the oxidize metal, M[I], to remove at least a portion of the at least one metal layer from the substrate thereby polishing the substrate.

According to other embodiments of the present invention, a chemical mechanical polishing system includes a polishing device including a polishing member support, and a polishing member coupled to the polishing member support for relative movement with the substrate, and a CMP composition provided at an interface between the polishing member and the substrate, wherein the CMP composition comprises a carbon dioxide-based solvent, an oxidizing agent capable of oxidizing a metal, M[0], to provide an oxidized metal, M[II], and a fluorinated beta-diketone chelating agent capable of chelating the oxidized metal, M[II].

According to still other embodiments of the present invention, a chemical mechanical polishing system includes a polishing device including a polishing member support, and a polishing member coupled to the polishing member support for relative movement with the substrate, and a CMP composition provided at an interface between the polishing member and the substrate, wherein the CMP composition comprises a carbon dioxide-based solvent, an oxidizing agent capable of oxidizing a metal, M[0], to provide an oxidized metal, M[I], and a chelating agent capable of chelating the oxidized metal, M[I].

According to yet other embodiments of the present invention, a method for endpoint detection in a CMP process includes removing a portion of a metal layer from a substrate using a chemical mechanical polishing composition that comprises an oxidizing agent, a chelating agent, and a carbon dioxide-based solvent, and detecting the presence of the metal in the chemical mechanical polishing composition to determine the endpoint of the CMP process.

### BRIEF DESCRIPTION OF THE DRAWINGS

The invention can be more readily ascertained from the following description of the invention when read in conjunction with the accompanying drawings in which:

FIG. 1 illustrates embodiments of a carbon dioxide based chelating composition according to the present invention at the initial time of reaction, immediately after mixing the composition with a copper coupon;

FIG. 2 illustrates embodiments of the carbon dioxide based chelating composition of FIG. 1 according to the present invention after contacting the copper coupon for 18 hours; and

FIG. 3 illustrates an XPS spectra of a composition according to embodiments of the present invention after the composition had contacted a copper coupon. The XPS spectra has a copper peak that correlates with a Cu(I) species, and iodide and phosphorus peaks show potential Cu(I) chelation.

### DETAILED DESCRIPTION OF THE INVENTION

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein the term “carbon dioxide based solvent” means a solvent comprising at least 65% (w/v) liquid or supercritical carbon dioxide.

According to embodiments of the present invention, a chemical mechanical polishing composition includes a carbon dioxide-based solvent, an oxidizing agent capable of oxidizing a metal, M[0], to provide an oxidized metal, M[II], and a fluorinated beta-diketone chelating agent.

In some embodiments, the carbon dioxide-based solvent is a liquid carbon dioxide-based solvent. When liquid carbon dioxide is used, the temperature employed during the process is below the critical temperature for carbon dioxide (approximately 31° C.). In some embodiments, the carbon dioxide-based solvent is a supercritical carbon dioxide-based solvent. As used herein, “supercritical” means that a fluid medium is at or above its critical temperature and pressure, i.e., 31.1° C. and 1070.6 psi for carbon dioxide. The thermodynamic properties of carbon dioxide are reported in Hyatt, J. Org. Chem. 49: 5097-5101 (1984); therein, it is stated that the critical temperature of carbon dioxide is about 31° C. For the purposes of the invention, it is preferred to employ carbon dioxide at a pressure ranging from a lower limit of about 200 psi to an upper limit of about 10,000 psi. More preferably, the carbon dioxide is employed at a pressure ranging from a lower limit of about 600 to an upper limit of about 6,000 psi.

In some embodiments, the metal is a copper containing metal. Preferably, the copper containing metal comprises at least 80% copper, and, more preferably, the copper containing metal comprises at least 90%, 95%, or more copper. In other embodiments, the metal is Cu[0] and the oxidized metal is Cu[II]. In still other embodiments, the metal may include aluminum, tungsten, tantalum, titanium, tantalum nitride or various other metals or alloys commonly used in the production of microelectronics, photoresist films, liquid crystal display applications, solar cells, laser diodes, lab-on-a-chip, microfuel cells, and light emitting diodes as will be understood by those skilled in the art.

The oxidizing agent may include various oxidizing agents that are capable of oxidizing a metal, M[0], to provide an oxidized metal, M[II], as will be understood by those skilled in the art. Such oxidizing agents may include, but are not limited to, organic peroxides, acids, molecular oxygen and oxygen containing materials (e.g., manganese dioxide, carbon monoxide, air, oxone, ozone, and perborates) molecular halogens (e.g., chlorine and iodine) and halogen containing agents (e.g., halides, chlorine dioxide, iodates, hypochlorite, perchlorates, periodates, nitrogen trifluoride), inorganic peroxides (including urea peroxide), transition metal complexes and ions (e.g., chromate and permanganate), sulfur-containing agents (e.g., carbonyl sulfide, sulfur dioxide, persulfates and sulfur trioxide), nitrogen containing agents (e.g., nitrates, isocyanates, cyanogen, azides, and nitrites, azo compounds, nitrous oxide, dinitrogen oxide), and acids, salts, and adducts thereof, as well as mixtures thereof.

In some embodiments, the oxidizing agent is preferably a peroxide. Suitable peroxides include, but are not limited to, organic peroxides (e.g., benzoyl peroxide, t-butyl peracetate, t-butyl peroxide, dialkyl peroxides, diacylperoxides, peroxydicarbonates, dialkyl peroxydicarbonates such as diethyl peroxydicarbonate, acetyl peroxide, lauryl peroxide, and cumyl peroxide), inorganic peroxides (e.g., persulfates and urea peroxide), hydroperoxides (e.g., t-butyl hydroperoxide), and mixtures thereof.

In some embodiments, the oxidizing agent is preferably a CO₂-soluble oxidizing compound. The CO₂-soluble oxidizing compound may be various CO₂-soluble oxidizing compounds including, but not limited to, CO₂-soluble peroxides and gaseous oxidants such as oxone, oxygen, dinitrogen oxide, chlorine dioxide, halogens, carbonyl sulfide, carbon monoxide, nitrous oxide, cyanogen, nitrogen trifluoride, sulfur dioxide, and sulfur trioxide, and mixtures thereof. CO₂-soluble peroxides include, but are not limited to, peroxydicarbonates (e.g., alkyl peroxydicarbonates such as ethyl peroxydicarbonate (EPDC) and bis-4-tertbutylcyclohexyl peroxydicarbonate such as Perkadox™ 16 available from Akzo Nobel, halogenated alkyl peroxydicarbonates, aryl peroxydicarbonates, halogenated aryl peroxydicarbonates, alkylaryl peroxydicarbonates, halogenated alkylaryl peroxydicarbonates, and halogenated peroxydicarbonates), fluorinated peroxides such as bis(trifluoroacetyl) peroxide and bis(2,3,3,3-tetrafluoro-2-(heptafluoropropoxy)-1-oxopropyl)peroxide (HFPO), diacetyl peroxide, and mixtures thereof. In preferred embodiments, the oxidizing agent is a CO₂-soluble compound selected from the group consisting of ethyl peroxydicarbonate, bis-4-tertbutylcyclohexyl peroxydicarbonate, bis(trifluoracetyl) peroxide, bis(2,3,3,3-tetrafluoro-2-(heptafluoropropoxy)-1-oxopropyl)peroxide, diacetyl peroxide, and mixtures thereof.

In some embodiments, the amount of the oxidizing agent in the chemical mechanical composition is in proportion to the amount of metal that one desires to remove from a metal layer. According to some embodiments, the amount of the oxidizing agent is preferably at least 0.5 times a mole equivalent amount of the metal to be removed from the metal containing layer. For example, when the metal is copper or a copper containing metal, the preferred amount would be one to two equivalents oxidant per copper or metal, alloy, or metal mixture desired to be removed. In some embodiments, the amount of the oxidizing agent could be from a lower limit of about 0.5, 1, or 2 to an upper limit of about 2, 10, or 20 times the mole equivalent of the metal to be removed from the metal containing layer.

In other embodiments, the amount of the oxidizing agent in the chemical mechanical composition is from a lower limit of about 0.1, 0.25, 0.5, 1, 2, 3, 4, or 5% (w/v) to an upper limit of about 4, 5, 6, 7, 8, 9, 10, 15, 20, 25, 30 or 35% (w/v).

According to some embodiments of the present invention, the chelating agent is a fluorinated beta-diketone chelating agent such as 1,1,1,5,5,5-hexafluoro-2,4-pentanedione (hfac) or 1,1,1-trifluoro-2,4-pentanedione (tfac). Fluorinated beta-diketone chelating agents may perform substantially better than beta-diketone in compositions employing a carbon dioxide-based solvent. Unlike beta-diketone, which may need to be combined with a base to form a deprotonated compound capable of chelation, fluorinated beta-diketone chelating agents of the present invention can be used in the absence of a base. Additionally, in contrast to beta-diketone, which forms less soluble metal chelates (i.e. metal(beta-diketonate) complexes or ions) in carbon dioxide, fluorinated beta-diketone chelating agents form more soluble chelated metal complexes or ions in carbon dioxide based-solvents. Accordingly, fluorinated beta-diketone chelating agents, in combination with CO₂-soluble oxidizing agents, provide homogeneous chemical mechanical compositions. When performing CMP, a homogeneous composition may be preferred because it might provide more uniform polishing of the semiconductor substrate. Additionally, homogeneous compositions generally give faster rates of reaction than heterogeneous compositions. Moreover, it may be easier (e.g., less complicated, less time, etc.) to separate CMP solution components from the metal surface. Such homogeneous compositions may have fewer components than heterogeneous compositions (e.g., no surfactant, no solid particles, etc.) and may provide easier manufacturing processes (e.g., no premixing required). Furthermore, such homogeneous solutions may allow the CMP process and the post-CMP cleaning to be performed using a non-aqueous, environmentally friendly solvent, namely a carbon dioxide-based solvent. Other CO₂-soluble additives such as CO₂-soluble corrosion inhibitors, CO₂-soluble co-solvents, CO₂-soluble acids, CO₂-soluble bases, CO₂-soluble surfactants, and CO₂-soluble catalysts described above can be included in the homogeneous compositions.

In some embodiments, the amount of chelating agent is determined by the amount of metal that one desires to remove from a metal layer or layers. The amount of the fluorinated beta-diketonate chelating agent is preferably at least about 1, 2, or 3 times of the number of moles of the metal to be removed from a metal containing layer. In some embodiments, the amount of the fluorinated beta-diketonate chelating agent is from a lower limit of about 1, 2, or 3 and an upper limit of about 2, 3, 10 or 20 times the number of moles of metal to be removed from a metal containing layer. In some embodiments, two moles (or equivalents) of fluorinated beta-diketonate chelating agent per copper atom to be removed is preferred. An excess of oxidant and/or chelator may make the reaction faster.

In other embodiments, the amount of the chelating agent in the chemical mechanical composition is from a lower limit of about 0.1, 0.25, 0.5, 1, 2, 3, 4, or 5% (w/v) to an upper limit of about 4, 5, 6, 7, 8, 9, 10, 15, 20, 25, 30 or 35% (w/v).

In some embodiments, the chemical mechanical composition further comprises one or more additives such as abrasive agents, corrosion inhibitors, co-solvents, acids, bases, surfactants, or catalysts. Additionally or alternatively, chemical mechanical compositions according to the present invention can include other additives as will be understood by those skilled in the art.

The abrasive agent may include various abrasive agents as will be understood by those skilled in the art including, but not limited to those disclosed in published U.S. Pat. No. 6,623,355 to McClain et al., the disclosure of which is incorporated herein by reference in its entirety. In some embodiments, the abrasive agent has a hardness of about 6 Mohs or greater. Such “hard” abrasive agents include, but are not limited to, alumina abrasive powders, silica abrasive powders, titania abrasive powders, sapphire abrasive powders, diamond abrasive powders, cerium abrasive powders, cubic boron nitride abrasive powders, and polymeric resins. In other embodiments, the abrasive agent has a hardness of less than about 6 Mohs. Such “soft” abrasive agents include, but are not limited to, mineral agents such as magnesium oxide. Using “soft” abrasive agents may be preferred when the metal is copper to reduce or eliminate the likelihood of scratching the copper surface during CMP. The amount of the abrasive agent is preferably from a lower limit of about 0.1, 0.5, or 1% (w/v) to an upper limit of about 2, 3, 4, 5, 6, 7, 8, 9, 10, 11, 12, 13, 14, 15, 20, 25, 30, or 35% (w/v). The amount of the abrasive agent is preferably from 0.1 to 5% (w/v).

The corrosion inhibitor is preferably selected to inhibit the corrosion (or oxidation) of the metal and includes, but is not limited to, triazoles, imidazoles, DNA bases, phosphate inhibitors, amines, pyrazoles, 2-hydroxyacetophenone-aroyl hydrazone inhibitors, triphenyl methane inhibitors, propanethiol, silanes, secondary amines, benzohydroxamic acids, heterocyclic nitrogen inhibitors, cyclic oxazolidines, citric acid, and mixtures thereof. Suitable triazoles include, but are not limited to, 1,2,4-triazole, benzotriazole, 5-methyl benzotriazole, and mixtures thereof. When included in the composition, the amount of the corrosion inhibitor is preferably from a lower limit of about 0.01, 0.05, 0.1, 0.5, or 1% (w/v) to an upper limit of about 0.1, 0.5, 1, 1.5, 2, 5, or 20%(w/v).

Co-solvents that may be used in carrying out the present invention are typically organic co-solvents including, but not limited to alcohols, preferably lower alkanols such as methanol or ethanol, ethyl acetate, tetrahydrofuran, alkanes, tetrahydrofuran, dimethylformamide, toluene, water, ketones such as acetone, aldehydes, and esters, dimethyl formamide, dimethyl sulfoxide, pyridine, acetonitrile, glycols, and mixtures thereof. Fluorosolvents, particularly those which are not gases may also be used. If used, the co-solvent may be employed in various amounts, preferably from a lower limit of about 0.1, 0.5, 1, 5, or 10% (w/v) to an upper limit of about 5, 10, 15, 20, 25, or 35% (w/v).

The acid may be a CO₂-soluble acid or a non-CO₂ soluble acid such as oxalic acid, succinic acid, citric acid, or mixtures thereof. In some embodiments, the acid is preferably a CO₂-soluble acid such as, but not limited to, acetic acid, hydrofluoric acid, Lewis acids, trifluoroacetic acid, tosic acid, tetrafluoroboric acid, methyl sulfonic acid, or mixtures thereof. If used, the acid may be employed in various amounts, preferably from a lower limit of about 0.1, 0.5, 1, 5, or 10% (w/v) to an upper limit of about 5, 10, 15, 20, 25, 30, or 35% (w/v).

The base which may be any of various bases including, but not limited to, amines, ammonium hydroxide, ammonia, pyridine-based materials, hydroxide, oxide, hypochlorite, and mixtures thereof. If used, the base may be employed in various amounts, preferably from a lower limit of about 0.1, 0.5, 1, 5, or 10% (w/v) to an upper limit of about 5, 10, 15, 20, 25, 30, or 35% (w/v).

The chemical mechanical polishing compositions may further comprise a surfactant or detergent. A surfactant preferably has a CO₂-philic moiety such that it is soluble in the carbon dioxide based solvent. Suitable surfactants include, but are not limited to, amphoteric salts, sodium dodecyl sulfate, alkyl ammonium, perfluoropolyether surfactants, cationic surfactants, anionic surfactants, zwitterionic surfactants, Aerosol-OT (AOT) and fluorinated analogues thereof, Ls-36 ™, Ls-45™, bis-(2-(F-hexyl)ethyl)phosphate salt) (DiF8), (2-(F-decyl)ethyl)octylphosphate salt (12-8, salt), 2-sulfosuccinate salts, phosphate-based surfactants, sulfur-based surfactants, acetoacetate based polymers, CO₂-philic surfactants such as those described in U.S. Pat. No. 5,783,082 to DeSimone et al, the disclosure of which is incorporated herein in its entirety, and mixtures thereof. If used, the surfactant or detergent may be employed in various amounts, preferably from a lower limit of about 0.01, 0.05, 0.1, 0.5, 1, 2.5, 5, or 10% (w/v) to an upper limit of about 5, 10, 15, 20, 25, 30, or 35% (w/v).

The catalyst may include a catalyst that promotes a chemical reaction between the oxidizing agent and a metal. The catalyst may include various catalysts such as, but not limited to, ruthenium-based catalysts, rhodium-based catalysts, iridium-based catalysts, solid or soluble catalysts as described in U.S. Pat. No. 6,362,104 to Wang et al., the disclosure of which is incorporated herein by reference in its entirety, or mixtures thereof. If used, a catalyst may be employed in various amounts, preferably from a lower limit of about 0.1, 0.5, 1, 5, or 10% (w/v) to an upper limit of about 5, 10, 15, 20, 25, 30, or 35% (w/v).

According to another aspect of the present invention, a composition includes a carbon dioxide-based solvent, an oxidizing agent, and a fluorinated beta-diketonate chelating agent. In some embodiments, the oxidizing agent is soluble in the carbon dioxide-based solvent, the fluorinated beta-diketonate chelating agent is soluble in the carbon dioxide-based solvent, and the composition is a homogeneous composition. The carbon dioxide-based solvent, the oxidizing agent, and the fluorinated beta diketonate chelating agent are as described above. In various embodiments, the composition can further include one or more of the various additives such as abrasive agents, corrosion inhibitors, co-solvents, acids, bases, surfactants, and catalysts described herein and/or various other additives or agents as will be understood by those skilled in the art.

According to yet another aspect of the present invention, a chemical mechanical polishing composition includes a carbon dioxide-based solvent, an oxidizing agent capable of oxidizing a metal, M[0], to provide an oxidized metal, M[I], and a chelating agent capable of chelating the oxidized metal, M[I]. The carbon dioxide-based solvent is similar to that described above. The metal is similar to the metals described above. Preferably, the metal is Cu[0] and the oxidized metal is Cu[I]. In various embodiments, the composition can further include one or more additives such as abrasive agents, corrosion inhibitors, co-solvents, acids, bases, surfactants, and catalysts described above.

The oxidizing agent may include various oxidizing agents that are capable of oxidizing a metal, M[0], to provide an oxidized metal, M[I], including, but not limited to, molecular halogen, permanganate, chlorine dioxide, transition metal complexes/ions, and nitrous acid. A molecular halogen is preferably molecular iodine.

In some embodiments, the amount of the oxidizing agent in the chemical mechanical composition is in proportion to the amount of metal that one desires to remove from a metal layer or layers. In certain embodiments, the amount of the oxidizing agent is preferably at least 0.5 times a mole equivalent amount of the metal to be removed from a metal containing layer. For example, when the metal is copper or a copper containing metal, the preferred amount would be one to two equivalents oxidant per copper or metal, alloy, or metal mixture desired to be removed. In some embodiments, the amount of the oxidizing agent could be from a lower limit of about 0.5, 1, or 2 to an upper limit of about 2, 10, or 20 times the mole equivalent of the metal to be removed. In other embodiments, the amount of the oxidizing agent in the chemical mechanical composition is from a lower limit of about 0.1, 0.25, 0.5, 1, 2, 3, 4, or 5% (w/v) to an upper limit of about 4, 5, 6, 7, 8, 9, 10, 15, 20, 25, 30 or 35% (w/v).

The chelating agent may include various chelating agents that are capable of complexing the oxidized metal, M[I], including, chelating agents that contain halogen, carbon, oxygen, sulfur, phosphorous, or nitrogen including, but not limited to, crown ethers including fluorinated and non-fluorinated crown ethers; halides; pyridine and pyridine-based chelating agents; imidazole and imidazole-based chelating agents; cyano chelating derivatives, triazoles, citrate, amine chelating agents such as benzylamine; carbon monoxide; water; acetonitrile; carbonate; oxide; phosphine chelating agents; phosphite chelating agents; phosphate chelating agents; hydroxide; methacrylate chelating agents; nitrate; nitrite; tetrafluoroborate; trifluoromethane sulfonate; tungstate; vanadate; thiophenolate; glucoxime, quinolines; fluorinated acrylates; fluorinated methacrylates; polymeric chelating agents such as those described in U.S. Pat. No. 6,176,895 to DeSimone et al., which describes chelating agents that comprise a plurality of chelating ligands coupled to a CO₂-philic polymer, the disclosure of which is incorporated herein by reference in its entirety, and mixtures thereof.

The chelating agent is preferably soluble in the carbon dioxide based solvent. Such chelating agents include, but are not limited to, carbon monoxide, fluorinated crown ethers, and phosphines (e.g., alkyl phosphines such as diethyl phosphine).

In some embodiments, the amount of chelating agent is determined by the amount of metal that one desires to remove from a metal layer and by the type of chelating agent (i.e., mono- or bi-dentate). When the chelating agent is a monodentate chelating agent, the amount of the chelating agent is preferably at least about 1, 2, 4 or 6 times number of moles of metal to be removed from a metal layer. In some embodiments, the amount of the monodentate chelating agent is from a lower limit of about 1, 2, 4, or 6 and an upper limit of about 4, 8, 10, or 20 times the number of moles of metal to be removed. When the chelating agent is a bidentate chelating agent, the amount of the chelating agent is preferably at least about 1, 2, or 3 times the number of moles of the metal to be removed. In some embodiments, the amount of the bidentate chelating agent is from a lower limit of about 1, 2, or 3 and an upper limit of about 2, 3, 10 or 20 times the number of moles of metal to be removed from a metal layer. For example, when the chelating agent is a bidentate chelating agent, two moles (or equivalents) chelating agent per copper atom to be removed is preferred, and when the chelating agent is a monodentate chelating agent, four moles (or equivalents) chelating agent per copper atom are preferred. An excess of oxidant and/or chelator may increase the rate of reaction.

In other embodiments, the amount of the chelating agent in the chemical mechanical composition is from a lower limit of about 0.1, 0.25, 0.5, 1, 2, 3, 4, or 5% (w/v) to an upper limit of about 4, 5, 6, 7, 8, 9, 10, 15, 20, 25, 30 or 35% (w/v).

In some embodiments, the oxidizing agent is soluble in the carbon dioxide-based solvent, the chelating agent is soluble in the carbon dioxide-based solvent, and the composition is a homogeneous composition. In a preferred embodiment, the CO₂-soluble oxidizing agent is an oxidizing agent capable of oxidizing Cu[0] in an at least one copper containing layer to Cu[I], and the CO₂-soluble chelating agent is capable of chelating Cu[I]. Other CO₂-soluble additives such as CO₂-soluble corrosion inhibitors, CO₂-soluble co-solvents, CO₂-soluble acids, CO₂-soluble bases, CO₂-soluble surfactants, and CO₂-soluble catalysts described above can be included in these homogeneous compositions.

According to still another aspect of the present invention, a homogeneous composition includes a carbon dioxide-based solvent, molecular iodine, and a phosphine that is soluble in the carbon dioxide-based solvent. Other CO₂-soluble additives such as CO₂-soluble corrosion inhibitors, CO₂-soluble co-solvents, CO₂-soluble acids, CO₂-soluble bases, CO₂-soluble surfactants, and CO₂-soluble catalysts described above as well as other CO₂-soluble additives and CO₂ insoluble additives such as abrasive agents as will be understood by those skilled in the art can be included in these homogeneous compositions.

While various separate compositions have been described above for oxidizing M[0] to M[I] and chelating M[l], for oxidizing M[0] to M[II] and chelating M[II], it is to be understood that such compositions may be used in combination. For example, compositions that include a carbon dioxide-based solvent, an oxidant capable of oxidizing M[0] to M[I], and oxidant capable of oxidizing M[0] to M[II], a chelating agent capable of chelating M[I], and a chelating agent capable of chelating M[II] are contemplated by the present invention.

According to another aspect of the present invention, a chemical mechanical composition for polishing a substrate comprises a carbon dioxide based solvent, and an oxidizing and chelating agent capable of oxidizing a metal and chelating the oxidized metal.

The oxidizing and chelating agent may be an oxidizing agent that is converted to a chelating agent after oxidizing a metal layer such as those described in U.S. Pat. No. 6,435,944 to Wang et al., the disclosure of which is incorporated herein by reference in its entirety. In some embodiments, suitable oxidizing and chelating agents include, but are not limited to, nitrates, hydroquinoline, quinolines, nitrites, aldehydes, ketones, and mixtures thereof. Compositions according to these embodiments may include one or more of the abrasive agents, corrosion inhibitors, co-solvents, acids, bases, surfactants, and catalysts described herein.

According to yet another aspect of the present invention, methods for polishing a substrate including at least one metal layer are provided. The methods include contacting the substrate with a chemical polishing composition such as any of the various compositions according to embodiments of the present invention described herein.

In some embodiments, the methods further include removing at least a portion of the metal layer from the substrate by bringing a pad into contact with the substrate and moving the pad in relation to the substrate. In such embodiments, the chemical polishing composition preferably further comprises an abrasive agent as described herein. In some embodiments, when the abrasive agent is a “soft” abrasive agent as described herein, the methods further include removing the chemical mechanical composition from the substrate, and contacting the substrate with a composition comprising a carbon dioxide-based solvent that comprises liquid or supercritical carbon dioxide to remove the CMP residue as described, for example, in published U.S. Pat. No. 6,623,355 to McClain et al.

According to another aspect of the present invention, methods for endpoint detection in a CMP process are provided. The methods include removing at least a portion of a metal layer from a substrate using a chemical mechanical polishing composition that comprises an oxidizing agent, a chelating agent, and a carbon dioxide-based solvent, and detecting the presence of the metal in the chemical mechanical polishing composition to determine the endpoint of the CMP process. In some embodiments, the metal is a metal ion. In other embodiments, the metal is a metal complex, for example a chelated metal ion.

In some embodiments, the process of detecting the presence of the metal in the chemical mechanical polishing composition includes detecting in situ the presence of the metal in the chemical mechanical polishing composition. In situ methods of detection include, but are not limited to, electrochemical methods such as cyclic and differential pulse voltammetries, atomic absorption, inductively coupled plasma, fluorescence, infrared, UV-Visible, electron paramagnetic resonance, and/or Raman spectroscopies. Preferably, detection is performed using UV-Visible spectroscopy.

According to yet another aspect of the present invention, a chemical mechanical polishing (CMP) system for polishing a substrate including at least one metal layer is provided. The system includes a polishing (or planarization) device including a polishing member support, and a polishing member coupled to the polishing member support for relative movement with the substrate, and a CMP composition provided at an interface between the polishing member and the substrate. The composition may be any of the various compositions according to embodiments of the present invention described above. Suitable polishing devices may be various polishing devices as will be understood by those skilled in the art including, but not limited to, those described in U.S. Pat. Nos. 4,671,851, 4,910,155, 4,944,836, and described in published U.S. Pat. No. 6,623,355 to McClain et al., the disclosures of each of which are incorporated herein by reference.

While certain embodiments of the present invention have been described in relation to chemical mechanical polishing compositions, it is to be understood that the compositions of the present invention may be used in various other semiconductor processes including, but not limited to, removal of contaminants containing copper especially in combination with other metals (for example Cu/Al alloys), removal of metals from photoresist films, removal of metals from liquid crystal displays, solar cells, laser diodes, light emitting diodes, microfuel cells, lab-on-a-chip, and etching processes.

Embodiments of the present invention are described with reference to the following examples. It should be appreciated that these examples are for the purposes of illustrating aspects of the present invention, and do not limit the scope of the invention as defined by the claims.

### EXAMPLE 1

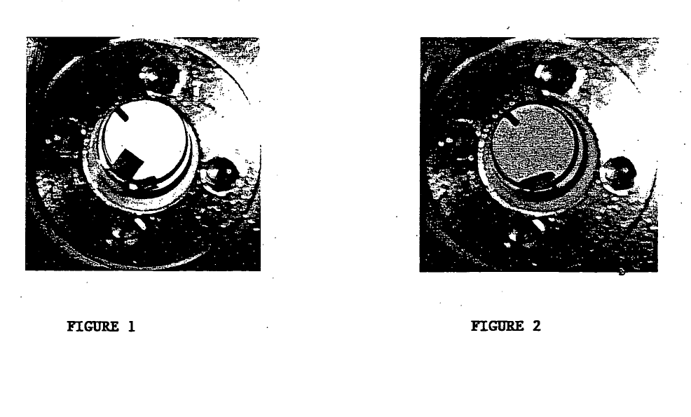

A 0.46 M solution of diethyl peroxydicarbonate in Freon 113 (3 w/v %, 0.42 mmol) and 6.5 w/v % (0.78 mmol) of 1,1,1,5,5,5-trifluoro-2,4-pentadione were syringed into a high pressure CO₂ view cell. A square copper coupon (0.12 g/1.9 mmol) was then placed into the cell, which was immediately charged with liquid CO₂ (3000 psi, 26° C.). A clear colorless composition (FIG. 1) was observed through the view cell prior to stirring with a flea bar. After stirring these reagents for 18 hours, a bright green clear composition was observed (FIG. 2).

### EXAMPLE 2

Cu(0) is oxidized and removed using molecular iodine (I₂) as the oxidant and triethylphosphine and the product of the oxidation (I⁻) are the chelating agents.

A 25 mL (internal volume) high pressure cell was utilized; In a glove box, the following reagents were placed in the high pressure view cell: 0.99 g I₂ (3.9 mmol), 0.55 mL triethyl phosphine (3.7 mmol), and a copper coupon weighing 0.23629 g (3.718×10⁻³). Liquid CO₂ was introduced into the cell at a pressure of approximately 3400 psi and room temperature. The temperature was raised to 40° C. (±2° C.), and the pressure equilibrated at approximately 4500 psi. The reaction progressed for 24 hours before the composition was vented into methanol. The copper was removed from the cell and weighed. The copper etched from the surface was calculated as 5.6%; additionally, the surface appeared to have a clear, shiny coating on both sides, indicative of the Cu(I) species.

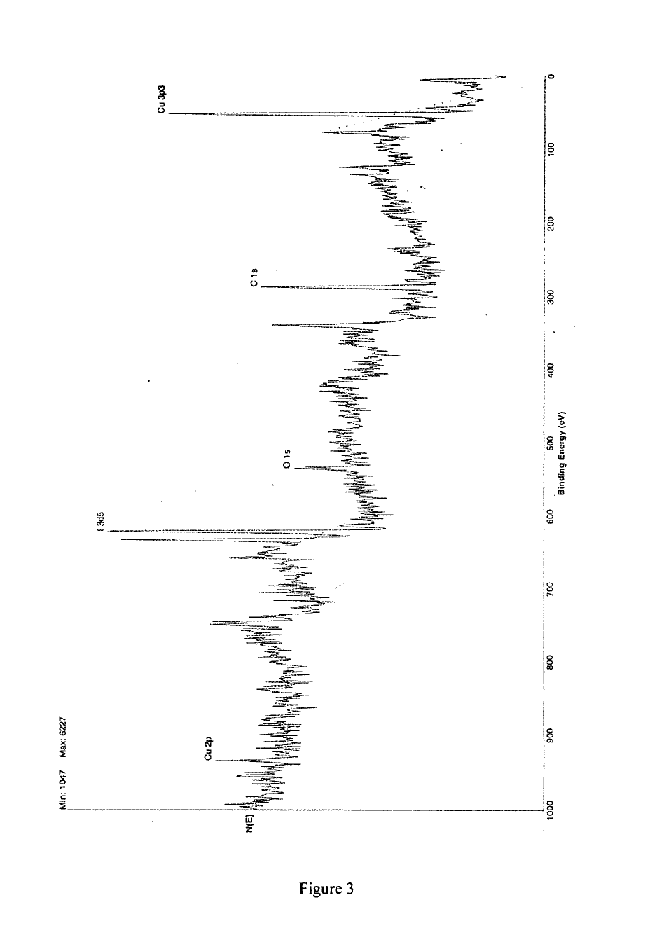

The XPS spectra shown in FIG. 3 has a copper peak that correlates with a Cu(I) species, and iodide and phosphorus peaks show potential Cu(I) chelation.

Having thus described certain embodiments of the present invention, it is to be understood that the invention defined by the appended claims is not to be limited by particular details set forth in the above description as many apparent variations thereof are possible without departing from the spirit or scope thereof as hereinafter claimed.

That which is claimed is:

1. A chemical mechanical polishing composition, comprising:
a carbon dioxide-based solvent;
an oxidizing agent capable of oxidizing a metal, M[0], to provide an oxidized metal, M[II]; and
a fluorinated beta-diketone chelating agent.

2. The composition according to claim 1, wherein the carbon dioxide-based solvent is a liquid carbon dioxide-based solvent.

3. The composition according to claim 1, wherein the carbon dioxide-based solvent is a supercritical carbon dioxide-based solvent.

4. The composition according to claim 1, wherein the metal is a copper containing metal.

5. The composition according to claim 1, wherein the metal comprises at least 80% copper.

6. The composition according to claim 1, wherein the oxidizing agent is selected from the group consisting of organic peroxides, acids, potassium permanganate, manganese dioxide, molecular halides, inorganic peroxides, persulfates, ozone, molecular oxygen, air, dinitrogen oxide, chlorine carbonate, cyanogens, azides, transition metal complexes, carbon monoxide, nitrous oxides, halogens, nitrogen trifluoride, sulfur dioxide, sulfur trioxide, isocyanates, chromates, hypochlorites, nitrates, nitrites, perchlorates, iodates, carbonyl sulfide, perborates, carbonyl sulfide periodates, oxone, acids thereof, salts thereof, adducts thereof, and mixtures thereof.

7. The composition according to claim 1, wherein the oxidizing agent is a CO₂-soluble peroxide.

8. The composition according to claim 1, wherein the peroxide is a peroxydicarbonate.

9. The composition according to claim 8, wherein the peroxydicarbonate is diethyl peroxydicarbonate.

10. The composition according to claim 1, wherein the fluorinated beta-diketonate chelating agent is selected from the group consisting of 1,1,1,5,5,5-hexafluoro-2,4, petanedione (hfac), 1,1,1-trifluoro-2,4-pentanedione (tfac), and mixtures thereof.

11. The composition according to claim 1, wherein the fluorinated beta-diketonate chelating agent is 1,1,1,5,5,5-hexafluoro-2,4, petanedione (hfac).

12. The composition according to claim 1, further comprising an abrasive agent.

13. The composition according to claim 12, wherein the abrasive agent has a hardness of about 6 Mohs or greater.

14. The composition according to claim 12, wherein the abrasive agent is selected from the group consisting of alumina abrasive powders, silica abrasive powders, and titania abrasive powders.

15. The composition according to claim 12, wherein the abrasive agent has a hardness of less than about 6 Mohs.

16. The composition according to claim 15, wherein the abrasive agent comprises magnesium oxide.

17. The composition according to claim 1, further comprising a corrosion inhibitor.

18. The composition according to claim 17, wherein the corrosion inhibitor is a triazole.

19. The composition according to claim 18, wherein the triazole is selected from the group consisting of 1,2,4-triazole and benzotriazole.

20. The composition according to claim 1, wherein the carbon dioxide based solvent further comprises a co-solvent.

21. The composition according to claim 20, wherein the co-solvent is an alcohol.

22. The composition according to claim 20, wherein the co-solvent is water.

23. The composition according to claim 1, further comprising an acid.

24. The composition according to claim 23, wherein the acid is a CO₂ soluble acid.

25. The composition according to claim 23, wherein the acid is selected from the group consisting of acetic acid, hydrofluoric acid, and trifluoroacetic acid.

26. The composition according to claim 1, further comprising a base.

27. The composition according to claim 1, further comprising a surfactant.

28. The composition according to claim 1, further comprising a catalyst for promoting a chemical reaction between the oxidizing agent and the metal.

29. A homogeneous composition, comprising:
a carbon dioxide-based solvent;
an oxidizing agent that is soluble in the carbon dioxide-based solvent; and
a chelating agent that is soluble in the carbon dioxide-based solvent.

30. The homogeneous composition of claim 29, wherein said oxidizing agent comprises an oxidizing agent capable of oxidizing a metal, M[0], to provide an oxidized metal M[II].

31. The homogeneous composition of claim 29, wherein said metal M[0] comprises Cu[0] and said oxidized metal M[II] comprises Cu[II].

32. The homogeneous composition of claim 29, wherein said oxidizing agent comprises an oxidizing agent capable of oxidizing a metal, M[0], to provide an oxidized metal M[I].

33. The homogeneous composition of claim 29, wherein said metal M[0] comprises Cu[0] and said oxidized metal M[II] comprises Cu[I].

34. The homogeneous composition of claim 29, wherein said chelating agent comprises a fluorinated beta-diketonate chelating agent.

35. The homogeneous composition of claim 29, wherein said chelating agent comprises a chelating agent capable of chelating M[I].

36. The composition according to claim 29, wherein said oxidizing agent is selected from the group consisting of molecular halogen, permanganate, chlorine dioxide, transition metal complexes, transition metal ions, nitrous acid, and mixtures thereof.

37. The composition according to claim 36, wherein said molecular halogen is molecular iodine.

38. The composition according to claim 29, wherein said chelating agent is a phosphine.

39. The composition according to claim 38, wherein said phosphine is an alkyl phosphine.

40. A chemical mechanical polishing composition, comprising:
a carbon dioxide based solvent comprising liquid or supercritical carbon dioxide; and
an oxidizing and chelating agent capable of oxidizing a metal and chelating the oxidized metal.

41. The composition according to claim 40, wherein the oxidizing and chelating agent is selected from the group consisting of hydroquinoline, quinolines, nitrites, aldehydes, ketones, and mixtures thereof.

42. A method for polishing a substrate, comprising:
contacting the substrate with a chemical mechanical polishing composition comprising a carbon dioxide-based solvent, an oxidizing agent capable of oxidizing a metal, M[0], to provide an oxidized metal, M[II], and a fluorinated beta-diketone chelating agent.

43. The method according to claim 42, wherein the oxidizing agent is a soluble peroxide

44. The method according to claim 42, wherein the contacting of the substrate with the chemical mechanical polishing composition further comprises:
contacting the substrate with a pad; and
moving the pad in relation to the substrate.

45. The method according to claim 44, wherein the chemical mechanical polishing composition further comprises an abrasive agent.

46. The method according to claim 42, wherein the metal comprises copper.

47. The method according to claim 42, wherein the metal, M[0], is Cu[0] and the oxidized metal, M[II], is Cu[II].

48. A method for polishing a substrate, comprising:
contacting the substrate with a chemical mechanical polishing composition comprising a carbon dioxide-based solvent, an oxidizing agent capable of oxidizing a metal, M[0], to provide an oxidized metal, M[I], and a chelating agent capable of chelating the oxidize metal, M[I].

49. The method according to claim 48, wherein the oxidizing agent is molecular iodine.

50. The method according to claim 48, wherein the chelating agent is a phosphine.

51. The method according to claim 48, wherein the contacting of the substrate with the chemical mechanical polishing composition further comprises:
contacting the substrate with a pad; and
moving the pad in relation to the substrate.

52. The method according to claim 51, wherein the chemical mechanical polishing composition further comprises an abrasive agent.

53. The method according to claim 48, wherein the metal comprises copper.

54. The method according to claim 48, wherein the metal, M[0], is Cu[0] and the oxidized metal, M[I], is Cu[I].

55. A chemical mechanical polishing (CMP) system, comprising:
a polishing device comprising a polishing member support, and a polishing member coupled to the polishing member support for relative movement with a substrate; and
a CMP composition provided at an interface between the polishing member and the substrate, wherein the CMP composition comprises a carbon dioxide-based solvent, an oxidizing agent capable of oxidizing a metal, M[0], to provide an oxidized metal, M[II], and a fluorinated beta-diketone chelating agent capable of chelating the oxidized metal, M[II].

56. A chemical mechanical polishing (CMP) system, comprising:
a polishing device comprising a polishing member support, and a polishing member coupled to the polishing member support for relative movement with a substrate; and
a CMP composition provided at an interface between the polishing member and the substrate, wherein the CMP composition comprises a carbon dioxide-based solvent, an oxidizing agent capable of oxidizing a metal, M[0], to provide an oxidized metal, M[I], and a chelating agent capable of chelating the oxidized metal, M[I].

57. A method for endpoint detection in a CMP process comprising:
removing a portion of a metal layer from a substrate using a chemical mechanical polishing composition comprising an oxidizing agent, a chelating agent, and a carbon dioxide-based solvent; and
detecting the presence of the metal in the chemical mechanical polishing composition to determine the endpoint of the CMP process.

58. The method according to claim 57, wherein the metal is a metal ion.

59. The method according to claim 57, wherein the metal is a metal complex.

60. The method according to claim 57, wherein the detecting of the presence of the metal in the chemical mechanical polishing composition comprises detecting the presence of the metal in the chemical mechanical polishing composition using a UV-visible spectrophotometer.
